(19) United States
(12) Patent Application Publication
(10) Pub. No.: US 2016/0133497 A1
(43) Pub. Date: May 12, 2016

(54) MULTI-LAYER LASER DEBONDING STRUCTURE WITH TUNABLE ABSORPTION

(71) Applicant: International Business Machines Corporation, Armonk, NY (US)

(72) Inventors: Paul S. Andry, Yorktown Heights, NY (US); Jeffrey D. Gelorme, Burlington, CT (US); Cornelia Kang-I Tsang, Mohegan Lake, NY (US); Bucknell C. Webb, Yorktown Heights, NY (US)

(21) Appl. No.: 14/535,909

(22) Filed: Nov. 7, 2014

(51) Int. Cl. H01L 21/683; B32B 7/12

(52) U.S. Cl. CPC H01L 21/6836; B32B 7/12; B32B 2307/4026; B32B 2457/14

(57) ABSTRACT

The absorption properties of both an adhesive layer and an ablation layer are employed to facilitate debonding of a device wafer and a glass handler without damaging the device wafer. The penetration depths of the adhesive and ablation layers are selected such that no more than a negligible amount of the ablation fluence reaches the surface of the device wafer.

### FIELD

The present disclosure relates to the fabrication of semiconductor devices and, more specifically, to wafer debonding.

### BACKGROUND

Three-dimensional (3D) chip technologies include 3D integrated circuits (IC) and 3D packaging. 3D chip technologies are gaining widespread importance as they allow for greater integration of more complex circuitry with shorter circuit paths allowing for faster performance and reduced energy consumption. In 3D ICs, multiple thin silicon wafer layers are stacked and interconnected vertically to create a single integrated circuit of the entire stack. In 3D packaging, multiple discrete ICs are stacked, interconnected, and packaged.

Modern techniques for 3D chip technologies, including both 3D ICs and 3D packaging, may utilize through-silicon vias (TSV). A TSV is a vertical interconnect access (VIA) in which a connection passes entirely through a silicon wafer or die. By using TSVs, 3D ICs and 3D packaged ICs may be more tightly integrated as edge wiring.

Temporary wafer bonding/debonding is an important technology for implementing TSVs and 3D silicon structures in general. Bonding in this context includes the act of attaching a silicon device wafer, which is to become a layer in a 3D stack, to a substrate or handling wafer so that it can be processed, for example, with wiring, pads, and joining metallurgy, while allowing the wafer to be thinned, for example, to expose the TSV metal of blind vias etched from the top surface. Debonding is the act of removing the processed silicon device wafer from the substrate or handling wafer so that the processed silicon device wafer may be added to a 3D stack.

Many existing approaches for temporary wafer bonding/debonding involve the use of an adhesive layer placed directly between the silicon device wafer and the handling wafer. When the processing of the silicon device wafer is complete, the silicon device wafer may be released from the handling wafer by various techniques such as by exposing the wafer pair to chemical solvents delivered by perforations in the handler, by mechanical peeling from an edge initiation point or by heating the adhesive so that it may loosen to the point where the silicon device wafer may be removed by sheering.

Debonding of a glass handler wafer from an adhesive-bonded device wafer has been effected through the use of an ablation layer applied to the glass handler wafer that is decomposed upon laser irradiation of a specified threshold value. Some of the laser fluence is absorbed by the ablation layer to enable wafer separation. The remainder penetrates the adhesive and/or the substrate.

### SUMMARY

Principles of the present disclosure provide an exemplary fabrication method that includes providing a laser device configured for emitting UV light of a selected wavelength and obtaining a structure comprising a device wafer, an adhesive layer adhered to the device wafer, a UV-transmissive handler, and an ablation layer between the handler and the adhesive layer and adhered to the adhesive layer. The ablation layer has an optical penetration depth of between 0.1 and 0.2 microns at the selected wavelength and has a thickness of at least two penetration depths. The adhesive layer has an optical penetration depth between two and twenty microns at the selected wavelength and a thickness of at least one penetration depth. The method further includes causing the laser device to emit UV light of the selected wavelength towards the structure and ablate the ablation layer and separating the handler from the device wafer.

An exemplary structure includes a device wafer, an adhesive layer adhered to the device wafer, the adhesive layer having an optical penetration depth of between two and twenty microns at a selected wavelength between 308 nm and 355 nm and a thickness of at least one penetration depth, a UV-transmissive handler, and an ablation layer between the UV-transmissive handler and the adhesive layer. The ablation layer has an optical penetration depth of between 0.1 and 0.2 microns at the selected wavelength and a thickness of at least two penetration depths. The ablation layer is further subject to decomposition upon being subjected to laser fluence.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor, by sending appropriate data or commands to cause or aid the action to be performed. For the avoidance of doubt, where an actor facilitates an action by other than performing the action, the action is nevertheless performed by some entity or combination of entities.

Fabrication methods as disclosed herein can provide substantial beneficial technical effects. For example, one or more embodiments may provide one or more of the following advantages:

Facilitates debonding of a handler from an adhesive-bonded device wafer;
Only a negligible amount of the starting fluence reaches the device wafer surface;
Provides for improved final process yield in the event that either the ablation coating or the adhesive coating contains a defect.

These and other features and advantages will become apparent from the following detailed description of illustrative embodiments thereof, which is to be read in connection with the accompanying drawings.

### BRIEF DESCRIPTION OF THE DRAWINGS

FIG. 1 is a schematic sectional illustration of a device wafer bonded to a glass handler;

FIG. 2A is a schematic sectional illustration showing a UV debonding process wherein laser fluence is absorbed by an ablation layer and an adhesive layer;

FIG. 2B is a graph showing the decline in intensity as a function of the thickness of the ablation layer in penetration depths, and

FIG. 2C is a graph showing the decline in intensity as a function of the thickness of the adhesive layer in penetration depths.

### DETAILED DESCRIPTION

Exemplary embodiments of the present invention provide various approaches for the temporary bonding and debonding of a silicon device wafer to a handling wafer or other substrate. A release layer, also referred to herein as an ablation layer, may be transparent so that the underlying circuitry of the silicon device wafer may be optically inspected prior to debonding. Debonding is performed by ablating the release layer using a laser. The laser used may be an ultraviolet (UV) laser, for example, a 355 nm laser, a 351 nm laser or a 308 nm laser. The 355 nm wavelength is particularly attractive due to the availability of robust and relatively inexpensive diode-pumped solid-state (DPSS) lasers.

The bonding of the silicon device wafer to the handling wafer includes the use of both an adhesive layer and a distinct release layer. According to one approach for such bonding, the release layer may be an ultraviolet (UV) ablation layer and it may be applied to the handling wafer, which is a glass handler in some exemplary embodiments. The UV ablation layer may then be cured. The bonding adhesive that forms the adhesive layer may be applied to either the glass handler or the silicon device wafer. The UV ablation layer is comprised of a material that is highly absorbing at the wavelength of the laser used in debonding. The material may also be optically transparent in the visible spectrum to allow for inspection of the adhesive bonded interface. Both the UV ablation layer as well as the bonding adhesive are chemically and thermally stable so that they can fully withstand semiconductor processes including heated vacuum depositions including PECVD and metal sputtering, thermal bake steps as well as exposure to wet chemistries including solvents, acids and bases (at the edge bead regions of the bonded wafer interface).

An exemplary fabrication method begins with UV ablation material being applied e.g. by spin coating onto the glass handler. The glass handler with UV ablation material spin-coated thereon is soft-baked to remove any solvent. Spin coating parameters may depend on the viscosity of the UV ablation layer, but may fall in the range from approximately 500 rpm to approximately 3000 rpm. The soft-bake may fall in the range from approximately 80° C. to approximately 120° C. The temperature of the final cure may fall in the range from 200° C. to 400° C. Higher cure temperatures may be more effective at ensuring thermal stability of the UV ablation layer during standard CMOS BEOL processing which may take place between 350° C. and 400° C. For strongly UV-absorbing or UV-sensitive materials, very thin final layers on the order of approximately 2000 Å to approximately 3000 Å thick may be sufficient to act as release layers. In some embodiments, the ablation layer has intrinsic UV-absorbing properties. Some organic planarizing layers (OPLs) and organic dielectric layers (ODLs) have such properties. In other embodiments, a dye is incorporated within the polymeric material comprising the ablation layer to impart the required UV-absorbing properties. Exemplary dyes that can be employed in one or more embodiments include 9-anthracenecarboxylic acid and benzanthrone added at a weight percentage of at least ten percent to any non-absorbing material capable of forming a film from solution such as polymethylmethacrylate (PMMA). The incorporation of dyes is discussed further below with respect to the adhesive layer. Some exemplary ODL materials are spin applied to glass and cured in a nitrogen environment at 350° C. for approximately one hour to produce a film. Such a film may be optically transparent throughout the visible spectrum, but strongly sensitive to decomposition in the UV wavelength range below about 360 nm, and may be fully and cleanly ablated using common UV laser sources such as an excimer laser operating at 308 nm (e.g. XeCl) or 351 nm (e.g. XeF) or a diode-pumped tripled YAG laser operating at 355 nm.

Laser debonding to release the glass handler at the ablation layer interface may be performed using any one of a number of UV laser sources including excimer lasers operating at 308 nm (e.g. XeCl) or 351 nm (e.g. XeF) as well as diode-pumped (tripled) YAG laser operating at 355 nm or diode-pumped (quadrupled) YAG laser operating at 266 nm. Excimer lasers may be more expensive, may require more maintenance/support systems (e.g. toxic gas containment) and may have generally have very large output powers at low repetition rates (e.g. hundreds of Watts output at several hundred Hz repetition). UV ablation thresholds in the materials specified here may require 100-150 milliJoules per square cm (mJ/sqcm) to effect release. Due to their large output powers, excimer lasers can supply this energy in a relatively large area beam having dimensions on the order of tens of square millimeters area (e.g. 0.5 mm times 50 mm line beam shape). Due to their large output power and relatively low repetition rate, a laser debonding tool which employs an excimer laser may include a movable x-y stage with a fixed beam. Stage movement may be on the order of ten to fifty mm per second. The wafer pair to be debonded may be placed on the stage and scanned back and forth until the entire surface had been irradiated.

An alternative laser debonding system may be created using a less expensive, more robust and lower power solid-state pumped tripled YAG laser at 355 nm by rapidly scanning a small spot beam across the wafer surface. The 355 nm wavelength laser may compare favorably to the quadrupled YAG laser at 266 nm for two reasons: 1) Output powers at 355 nm are typically two to three times larger than at 266 nm for the same sized diode laser pump power, and 2) many common handler wafer glasses (for example, Schott Borofloat 33) are about ninety percent or more transmissive at 355 nm but only about fifteen percent transmissive at 266 nm. Since eighty percent of the power is absorbed in the glass at 266 nm, starting laser powers may be about six times higher to achieve the same ablation fluence at the release interface. There is accordingly some risk of thermal shock in the glass handler itself.

An exemplary 355 nm scanning laser debonding system may include the following: 1) a Q-switched tripled YAG laser with an output power of 5 to 10 Watts at 355 nm, with a repetition rate between 50 and 100 kHz, and pulsewidth of between 10 and 20 ns. The output beam of this laser may be expanded and directed into a commercial 2-axis scanner, comprising mirrors mounted to x and y galvanometer scan motors. The scanner may be mounted a fixed distance above a fixed wafer stage, where the distance would range from 20 cm to 100 cm depending on the working area of the wafer to be released. A distance of 50 to 100 cm may effectively achieve a moving spot speed on the order of 10 meters/second. An F-theta lens may be mounted at the downward facing output of the scanner, and the beam may be focused to spot size on the order of 100 to 500 microns. For a six watt output power laser at 355 nm, at 50 kHz repetition and 12 ns pulsewidth, a scanner to wafer distance of 80 cm operating at a raster speed of 10 m/s, the optimal spot size may be on the order of 200 microns, and the required about 100 mJ/sq. cm ablation fluence may be delivered to the entire wafer surface twice in about thirty seconds (for example, using overlapping rows). The use of overlapping rows where the overlap step distance equals half the spot diameter (e.g., 100 microns) may ensure that no part of the wafer is missed due to gaps between scanned rows and that all parts of the interface see the same total fluence.

An exemplary approach for performing handler wafer bonding and debonding in accordance with exemplary embodiments of the present invention includes applying the release layer to the handler while an adhesive layer may be applied to the device wafer. However, according to other exemplary approaches, the release layer may be applied to the handler and then the adhesive layer may be applied to the release layer. The release layer is interposed between the glass handler and the adhesive. Thereafter, the device wafer may be bonded to the handler such that the release layer and the adhesive layer are provided between the device wafer and the handler. The bonding may include a physical bringing together of the device wafer and the handler under controlled heat and pressure in a vacuum environment such as offered in any one of a number of commercial bonding tools. After the device wafer has been successfully bonded to the handler, desired processing may be performed. Such processing may include such process steps as patterning, etching, thinning, etc. until the device wafer has achieved its desired state. Thereafter, the circuitry of the device wafer may be inspected. Inspection of the device circuitry may be performed to ensure that the device wafer has been properly processed. Inspection may be optically performed, for example, using a high quality microscope or other imaging modality. Optical inspection may be performed though the handler, which, as described above, may be transparent. Optical inspection of the device circuitry may also be performed through the release and adhesive layers as each of these layers may be transparent as well. Laser ablation is employed to allow separation of the device wafer from the handler along the plane of the ablation layer. For pulses in the range of 10-20 nanoseconds, ablation may include photothermal, photomechanical and/or photochemical ablation of the ablation layer. The device wafer is then cleaned to remove residual adhesive.

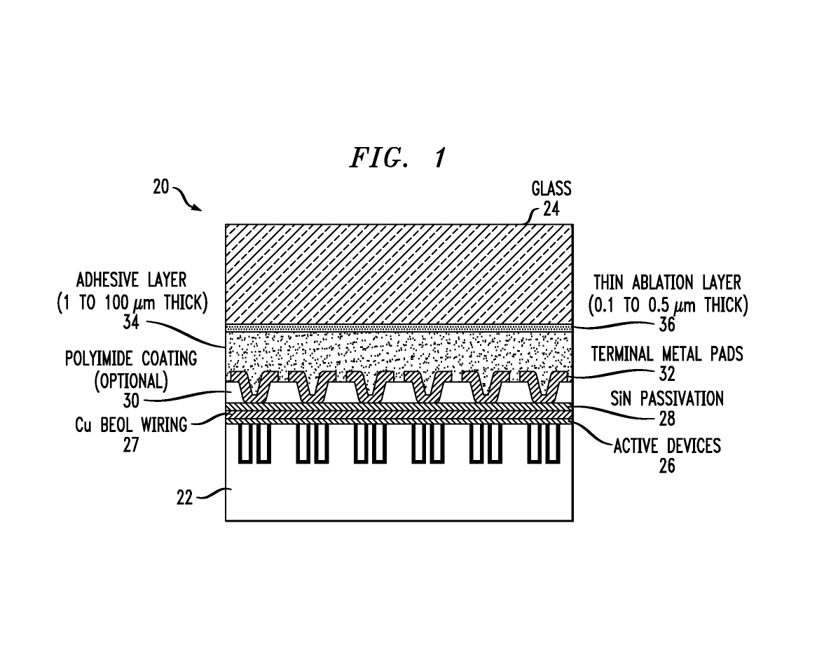

FIG. 1 schematically illustrates an exemplary structure 20 including a device wafer 22 bonded to a glass handler 24. The exemplary structure further includes active devices 26 on the device wafer 22, a wiring layer 27 formed during back-end-of-line (BEOL) processing, a passivation layer 28 comprising, for example, silicon nitride, an optional polyimide coating 30, terminal metal pads 32, an adhesive layer 34 and an ablation layer 36 between the handler 24 and the adhesive layer 34. In the exemplary structure, the ablation layer has a thickness between 0.1-0.5 μm. The adhesive layer has a substantially greater thickness of between 1-100 μm.

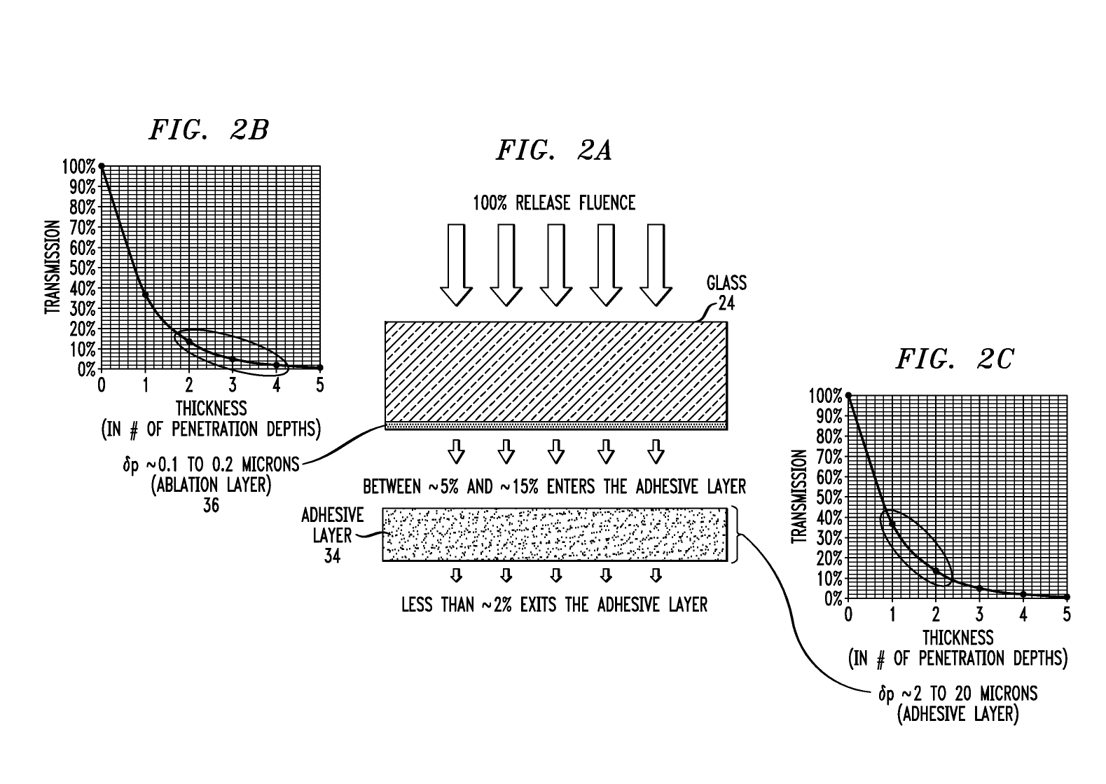

As discussed above, the ablation layer 36 is chosen to be highly absorptive in the ultraviolet spectrum of interest, namely between 308 nm and 355 nm. In some embodiments, about eighty to ninety percent of the laser fluence is absorbed by the ablation layer. Such absorption enables wafer separation as the ablation layer disintegrates. The remainder of the fluence penetrates into the adhesive layer. In the exemplary structure 20, the adhesive layer is also capable of absorbing fluence at the desired wavelengths (308-355 nm). By providing an ablation layer and an adhesive layer that both have absorption properties, as discussed further below, only a negligible amount of the starting fluence is allowed to reach the device wafer surface. FIG. 2A schematically illustrates the operation of the structure 20.

Penetration depth is a measure of the depth electromagnetic radiation can penetrate into a material, specifically the depth at which the intensity of the radiation falls to 1/e or about 36.8% of its original value at the substrate surface. Penetration depth δₚ is generally a function of wavelength for a given material. Intensity decreases as a function of thickness measured in penetration depths. For example, while intensity is about 36.8% of the original intensity at one penetration depth, it is only about 13.5% of the original intensity at two penetration depths and about five percent at three penetration depths. Referring again to FIG. 2A, UV light 40 is directed to the handler 24. In the exemplary embodiment, only about five to fifteen percent of the fluence at the surface of the handler enters the adhesive layer 34, due largely to the absorption by the ablation layer 36. The adhesive layer allows less than about two percent of the original fluence to exit towards the device wafer 22. The exemplary graphs shown in FIGS. 2B and 2C illustrate, respectively, transmission (as a percentage of original fluence) for the ablation layer and adhesive layer, respectively as a function of penetration depths. In the exemplary embodiments, the penetration depth of the ablation layer is between about 0.1-0.2 μm while the penetration depth of the thicker adhesive layer is between two and twenty micrometers. The ablation layer is one or more embodiments is on the order of 0.2-0.3 μm in thickness. This confines the laser pulse energy (about one hundred mJ/cm² for about ten nanoseconds duration in some embodiments) to a very thin zone adjacent to the handler to achieve complete release at reasonable fluence.

Certain high-temperature polymer adhesives based on polyimide absorb UV radiation in the wavelength range between 360 nm and 300 nm and comprise the adhesive layer in some embodiments. Thus, the amount of residual UV fluence reaching the active wafer surface can vary depending on the thickness uniformity of the original ablation layer and the optical properties and thickness of the adhesive layer below. Coating defects in the ablation layer may lead to yield loss unless there is additional filtering of the UV pulse over the substantially greater thickness of the adhesive layer. The adhesive layer employed in the fabrication processes disclosed herein, as combined with the ablation layer, have the necessary optical properties to help prevent laser induced damage that could result from an appreciable amount of the ablation pulse reaching the active wafer surface where it could interact with materials such as polyimide or PECVD silicon nitride (SiNₓ) passivation layers. Process yield can accordingly be improved as, in the event that either the ablation layer or the adhesive layer contains a defect, random defects are unlikely to occur in the same location for two separately applied materials.

In accordance with one or more embodiments, a multi-layer debonding structure includes two distinct layers, namely the ablation layer and the adhesive layer, having absorption properties and thicknesses that ensure that no more than a negligible amount of the ablation fluence is allowed to reach the device wafer surface. By specifying the required UV absorption requirements of both the ablation layer and the underlying adhesive, such as shown in FIGS. 2B and 2C, debonding can be safely conducted without a substantial risk of causing laser induced damage. In the exemplary embodiments, the ablation layer 36 has a thickness of at least two penetration depths, and preferably between two and four penetration depths. The adhesive layer has a thickness of at least one penetration depth and preferably between one and two penetration depths. The penetration depth of the ablation layer is between 0.1 and 0.2 microns in one or more embodiments while the penetration depth of the adhesive layer is between two and twenty microns in one or more embodiments.

In some embodiments, the adhesive layer has intrinsic optical absorption properties in the desired range of wavelengths. An exemplary commercial adhesive which readily absorbs UV laser radiation in the wavelength range from 300 nm to 360 nm would be the polyimide-based product by HD Microsystems called HD-3007 Adhesive. This commercial adhesive is a non-photodefinable polyimide precursor designed for use as a temporary or permanent adhesive in 3D packaging applications. It exhibits thermoplastic behavior after cure and during bonding at moderate temperature and pressure. Thermoplastic adhesives having base materials that do not have intrinsic optical absorption at the laser wavelength(s) desired, or have insufficient optical absorption properties, are modified in some embodiments by the addition of fine nanoparticles. Suspensions of the nanoparticles can be added in amounts which, when uniformly dispersed throughout the adhesive, lead to the approximation of a neutral density filter which scatters a known percentage of the incoming laser pulse with little dependence on wavelength. Exemplary nanoparticles include aluminum and alumina nanoparticles. In other exemplary embodiments, dyes are added to thermoplastic adhesives that do not exhibit the desired absorption properties. Some dyes are known to absorb in the laser wavelengths employed in one or more embodiments. As disclosed, for example, in U.S. Pat. No. 5,169,678, which is incorporated by reference herein, various dyes can be added to polymeric materials to affect the absorbance thereof. In some examples, the polymer is melted and the dye is added to the polymer melt. In other examples, the dye is diffused or dissolved into the polymer using a solvent. Even distribution of the dye is obtained in some embodiments. Dyes such as p-phenylazophenol, N-p methoxybenzylidene-p-phenylazoaniline, dihydroxyanthraquinone and beta carotine are among those that may be employed to provide absorbance in the UV range. Such dyes may be used as formulated in some embodiments or with substitutions to adjust the absorbance frequencies. Exciton products such as “DPS” (CAS 2039-68-1) and “Bis MSB” (CAS 13280-61-0) are other exemplary materials that can be employed within polymers to provide absorbance in the UV range in one or more embodiments. Further exemplary dyes that can be employed in one or more embodiments include 9-anthracenecarboxylic acid and benzanthrone.

An exemplary coating process for either the thin ablation layer or the HD-3007 adhesive includes dispensing of a few ml of the material, spin applying at between 1000 and 3000 rpm for sixty seconds, baking at about 110° C. to drive off the solvent, and curing on a hotplate or in a nitrogen oven at about 350° C. for ten minutes. A specific bonding recipe for HD-3007 adhesive includes aligning the adhesive-coated wafer to the handler, holding them apart by a small distance using spacers, and introducing the wafer pair into a chamber where vacuum would be pulled, such that the space between them is fully evacuated. The temperature would ramp up to above 100° C. to help degas the adhesive, and the spacers would be removed to place the wafer and handler in contact. Heating plates above and below would ramp up to a final bonding temperature of between 300° C. and 350° C., and a pressure of about 8000 mbar would be applied to the pair for five minutes to effect bonding. The pair would be held under pressure as the plates ramped back down to below the glass transition temperature Tg.

Given the discussion thus far and with reference to the exemplary embodiments discussed above and the drawings, it will be appreciated that, in general terms, an exemplary fabrication method includes providing a laser device configured for emitting UV light of a selected wavelength and obtaining a structure comprising a device wafer, an adhesive layer adhered to the device wafer, a UV-transmissive handler, and an ablation layer between the handler and the adhesive layer and adhered to the adhesive layer. The ablation layer has an optical penetration depth of between 0.1 and 0.2 microns at the selected wavelength and has a thickness of at least two penetration depths. The adhesive layer has an optical penetration depth between two and twenty microns at the selected wavelength and a thickness of at least one penetration depth. The method further includes causing the laser device to emit UV light of the selected wavelength towards the structure (such as shown in FIG. 2A) and ablate the ablation layer and separating the handler from the device wafer. The selected wavelength is between 308 nm and 355 nm in one or more embodiments. In some embodiments, the device wafer comprises silicon. Some embodiments of the method further include the steps of forming active semiconductor devices 26 using the device wafer and forming a metal wiring layer 27 on the device wafer. In some exemplary embodiments, the adhesive layer includes a dye that absorbs light of the selected wavelength. The ablation layer includes a dye that absorbs light of the selected wavelength in some embodiments. The adhesive layer may include nanoparticles uniformly dispersed therein. In some embodiments, the ablation layer and the adhesive layer allow two percent or less of laser fluence originating from the laser device to exit the adhesive layer, as schematically illustrated in FIG. 2A.

An exemplary structure, such as shown schematically in FIG. 1, includes a device wafer 22, an adhesive layer 34 adhered to the device wafer, the adhesive layer having an optical penetration depth of between two and twenty microns at a selected wavelength between 308 nm and 355 nm and a thickness of at least one penetration depth, a UV-transmissive handler 24, and an ablation layer 36 between the UV-transmissive handler and the adhesive layer. The ablation layer has an optical penetration depth of between 0.1 and 0.2 microns at the selected wavelength and a thickness of at least two penetration depths. The ablation layer is further subject to decomposition upon being subjected to laser fluence. The handler consists essentially of a glass material substantially transparent to the selected wavelength in one or more embodiments. The ablation layer 36 has intrinsic optical absorption properties at the selected wavelength in some embodiments. In other embodiments, the ablation layer 36 includes a dye that absorbs light of the selected wavelength. In one or more embodiments, the ablation layer is an organic planarizing layer. The thickness of the ablation layer is between two and four penetration depths in some embodiments. The thickness of the adhesive layer is between one and two penetration depths in some embodiments.

Those skilled in the art will appreciate that the exemplary structures discussed above can be distributed in raw form or incorporated as parts of intermediate products or end products such as integrated circuits.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof Terms such as “above” and “below” are used to indicate relative positioning of elements or structures to each other as opposed to relative elevation. It should also be noted that, in some alternative implementations, the steps of the exemplary methods may occur out of the order noted in the figures. For example, two steps shown in succession may, in fact, be executed substantially concurrently, or certain steps may sometimes be executed in the reverse order, depending upon the functionality involved.

The corresponding structures, materials, acts, and equivalents of all means or step plus function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the various embodiments with various modifications as are suited to the particular use contemplated.

1-9. (canceled)

10. A structure comprising:
a device wafer;
an adhesive layer adhered to the device wafer, the adhesive layer having an optical penetration depth of between two and twenty microns at a selected wavelength between 308 nm and 355 nm and a thickness of at least one penetration depth;
a UV-transmissive handler;
an ablation layer between the UV-transmissive handler and the adhesive layer, the ablation layer having an optical penetration depth of between 0.1 and 0.2 microns at the selected wavelength and having a thickness of at least two penetration depths, the ablation layer being further subject to decomposition upon being subjected to laser fluence.

11. The structure of claim 10, wherein the handler consists essentially of a glass material substantially transparent to the selected wavelength.

12. The structure of claim 11, wherein the adhesive layer includes a dye that absorbs light of the selected wavelength.

13. The structure of claim 11, wherein the adhesive layer includes nanoparticles suspended therein for scattering UV light of the selected wavelength.

14. The structure of claim 10, wherein the adhesive layer has instrinsic optical absorption properties at the selected wavelength.

15. The structure of claim 10, wherein the ablation layer has intrinsic optical absorption properties at the selected wavelength.

16. The structure of claim 15, wherein the ablation layer comprises an organic planarizing layer.

17. The structure of claim 10, wherein the ablation layer includes a dye that absorbs light of the selected wavelength.

18. The structure of claim 10, wherein the ablation layer has a thickness of less than 0.5 μm.

19. The structure of claim 10 wherein the thickness of the ablation layer is between two and four penetration depths at the selected wavelength.

20. The structure of claim 19 wherein the thickness of the adhesive layer is between one and two penetration depths at the selected wavelength.
